(19) United States
(12) Patent Application Publication
(10) Pub. No.: US 2024/0186123 A1
(43) Pub. Date: Jun. 6, 2024

(54) Heated Pedestal With Impedance Matching Radio Frequency (RF) Rod

(71) Applicant: Applied Materials, Inc., Santa Clara, CA (US)

(72) Inventors: Yao-Hung YANG, Santa Clara, CA (US); Chih-Yang CHANG, Santa Clara, CA (US); Yikai CHEN, Santa Clara, CA (US); Rongping WANG, Cupertino, CA (US)

(21) Appl. No.: 18/074,385

(22) Filed: Dec. 2, 2022

(51) Int. Cl. H01J 37/32

(52) U.S. Cl. CPC H01J 37/32724; H01J 37/32183

(57) ABSTRACT

Embodiments of substrate supports for process chambers are provided herein. In some embodiments, a substrate support for a process chamber includes: a pedestal having a support surface for supporting a substrate, one or more heating elements disposed therein, and a radio frequency (RF) electrode disposed therein; a hollow shaft coupled to a lower surface of the pedestal; and an RF rod extending through the hollow shaft and coupled to the RF electrode, wherein an impedance of the RF rod is less than about 0.2 ohms.

### FIELD

Embodiments of the present disclosure generally relate to substrate processing equipment.

### BACKGROUND

In the manufacture of integrated circuits and other electronic devices, plasma process chambers are often used for deposition or etching of various material layers. Plasma process chambers generally include heated pedestals for supporting a substrate during processing and controlling the temperature of the substrate during processing. During the life of a plasma process chamber, the heated pedestal may be refurbished to extend chamber life or replaced to accommodate different processes. However, a refurbished pedestal or a different pedestal may cause an impedance mismatch where an input impedance of an electrical load does not match an output impedance of the signal source, resulting in signal reflection or an inefficient power transfer to cause process shift.

Accordingly, the inventors have provided herein embodiments of improved substrate supports for use in plasma process chambers.

### SUMMARY

Embodiments of substrate supports for process chambers are provided herein. In some embodiments, a substrate support for a process chamber includes: a pedestal having a support surface for supporting a substrate, one or more heating elements disposed therein, and a radio frequency (RF) electrode disposed therein; a hollow shaft coupled to a lower surface of the pedestal; and an RF rod extending through the hollow shaft and coupled to the RF electrode, wherein an impedance of the RF rod is less than about 0.2 ohms.

In some embodiments, a substrate support for a process chamber includes: a pedestal having one or more heating elements and an RF electrode disposed therein and a support surface for supporting a substrate; a hollow shaft coupled to a lower surface of the pedestal; and an RF rod extending through the hollow shaft and coupled to the RF electrode, wherein an impedance of the RF rod is less than about 0.2 ohms, and wherein the RF rod is coupled to an impedance adjustment device.

In some embodiments, a process chamber includes: a chamber body defining an interior volume therein; a substrate support disposed in the interior volume and including a pedestal, having one or more heating elements and an RF electrode disposed therein and a support surface for supporting a substrate, and a hollow shaft coupled to a lower surface of the pedestal; and an RF rod extending through the hollow shaft and coupled to the RF electrode, wherein an impedance of the RF rod is less than about 0.2 ohms.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber in accordance with at least some embodiments of the present disclosure.

FIG. 2 depicts an isometric view of a substrate support in accordance with at least some embodiments of the present disclosure.

FIG. 3 depicts a schematic cross-sectional side view of a portion of a substrate support in accordance with at least some embodiments of the present disclosure.

FIGS. 4A-4G depict various cross-sectional shapes of an RF rod in accordance with at least some embodiments of the present disclosure.

FIGS. 5A-5B depict various side profiles of an RF rod in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of substrate supports for process chambers are provided herein. The inventors have observed that substrate supports having a higher impedance than a threshold substrate support may lead to reduced deposition rates during processing. The substrate support generally includes a pedestal coupled to a radio frequency (RF) rod having a reduced impedance to facilitate matching an impedance of the threshold substrate support. In some embodiments, the substrate support includes an adjustable impedance device coupled to the RF rod and configured for adjusting the impedance of the substrate support to match the threshold substrate support before installing in the process chamber.

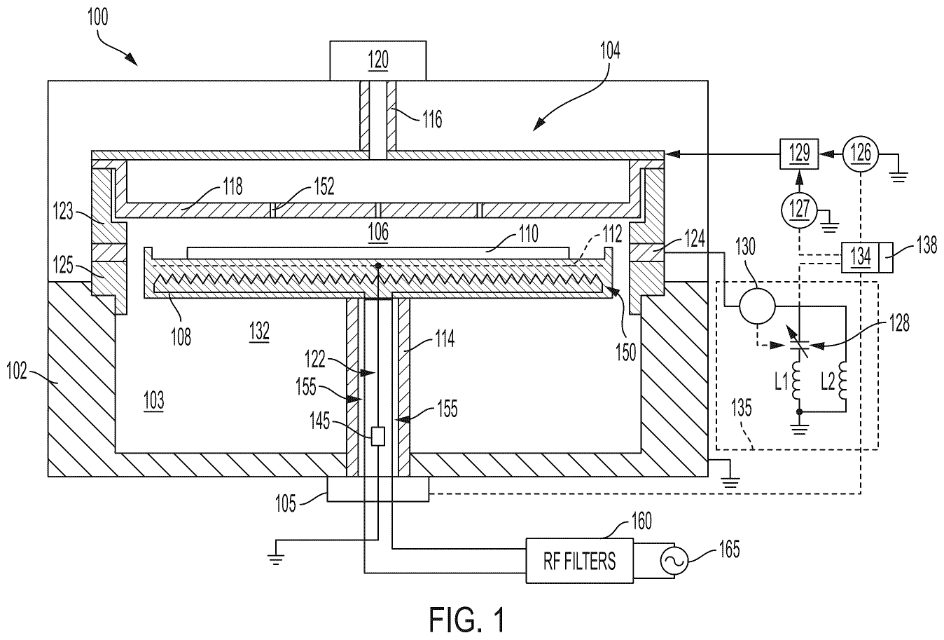

FIG. 1 is a schematic side cross-sectional depiction of a plasma processing chamber, according to at least some embodiments of the present disclosure. The plasma process chamber, or chamber 100, generally includes a chamber body 102 defining an interior volume 103 therein. A substrate support 108 is disposed in the interior volume 103 to support a substrate 110 disposed thereon. The chamber 100 is generally configured to deposit or etch one or more films onto or off of the substrate 110. The chamber 100 further includes a gas distribution assembly 104, which distributes gases uniformly into a process volume 106 of the interior volume 103 that is generally defined by a region between the gas distribution assembly 104 and the substrate support 108.

The substrate support 108 includes a pedestal 132 coupled to a hollow shaft 114. The pedestal 132 is movably disposed in the interior volume 103 via the hollow shaft 114 that extends through the chamber body 102 and connected to a drive system 105 and bellows to allow the pedestal 132 to be raised, lowered, and/or rotated.

The gas distribution assembly 104 includes a gas inlet passage 116, which delivers gas from a gas flow controller 120 into a gas distribution manifold 118. The gas distribution manifold 118 includes a plurality of holes 152, or nozzles, through which gaseous mixtures are injected into the process volume 106 during processing.

A high frequency RF power source 126 and a low frequency RF power source 127 provide electromagnetic energy through a match circuit 129 to power the gas distribution manifold 118, which acts as an RF powered electrode, to facilitate generation of a plasma within the process volume 106 between the gas distribution manifold 118 and the pedestal 132. The pedestal 132 includes a RF electrode 112, which is electrically grounded through an RF rod 122, such that an electric field is generated in the chamber 100 between the gas distribution manifold 118 that is powered and the RF electrode 112. The RF rod 122 may be made of copper, nickel, or the like. In some embodiments, the RF electrode 112 comprises a conductive mesh, such as a tungsten or molybdenum containing mesh that is disposed within the dielectric material that is used to form the pedestal 132. The pedestal 132 may include a ceramic material, such as aluminum nitride (AlN), silicon nitride (SiN), silicon carbide (SiC), or the like.

A ceramic ring 123 is positioned below the gas distribution manifold 118. Optionally, a tuning ring 124 is disposed between the ceramic ring 123 and an isolator 125, which electrically isolates the tuning ring 124 from the chamber body 102. The tuning ring 124 is typically made from a conductive material, such as aluminum, titanium, or copper. As depicted in FIG. 1, the optional tuning ring 124 is positioned concentrically about the pedestal 132 and substrate 110 during processing of the substrate 110. The tuning ring 124 may be electrically coupled to an RF tuner 135, which includes a variable capacitor 128, such as a variable vacuum capacitor, that is terminated to ground through an inductor L1. The RF tuner 135 also includes a second inductor L2 that is electrically coupled in parallel to the variable capacitor 128 to provide a path for low frequency RF to ground. The RF tuner 135 also includes a sensor 130, such as a voltage/current (V/I) sensor, that is positioned between the tuning ring 124 and the variable capacitor 128 for use in controlling the current flow through the tuning ring 124 and the variable capacitor 128.

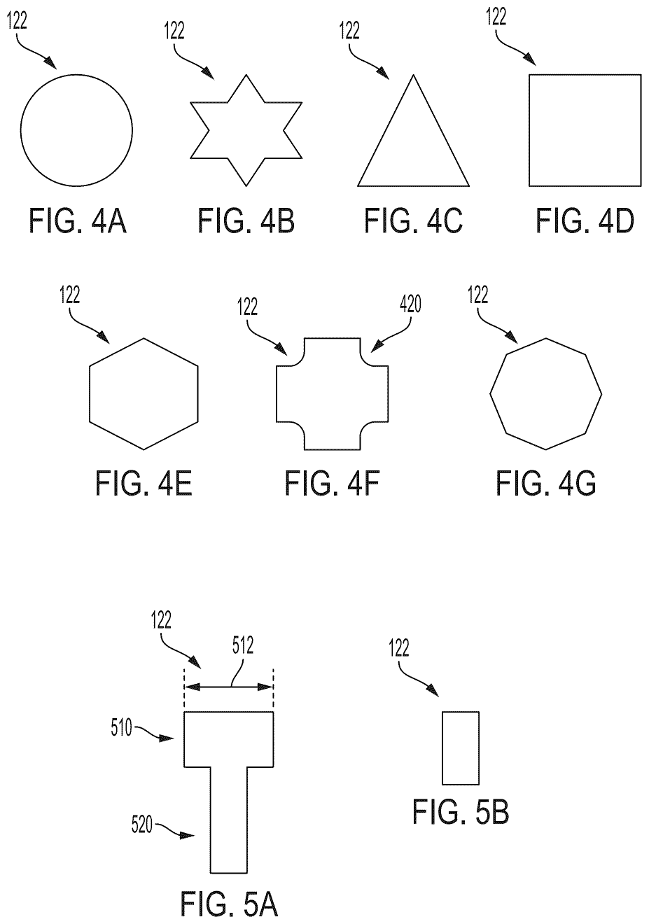

In some embodiments, the RF rod 122 is coupled to an impedance adjustment device 145 having at least one of a variable inductor or a variable resistor (discussed in more detail with respect to FIG. 4). The impedance adjustment device 145 may advantageously be used to tune the substrate support 108 to a target impedance value. In some embodiments, the target impedance of the RF rod 122 is less than about 0.2 ohms. In some embodiments, the impedance of the RF rod 122 is less than about 0.17 ohms. In some embodiments, the impedance of the RF rod 122 is less than about 0.17 ohms. In some embodiments, the impedance adjustment device 145 is configured to change the impedance of the RF rod 122 by about 0.05 to about 0.1 ohms.

One or more heating elements 150 are disposed within the pedestal 132 and are used to control a temperature profile across the substrate 110. In some embodiments, the heating elements 150 is disposed beneath the RF electrode 112. The heating elements 150 generally provide resistive heating to the substrate 110 and may be comprised of any feasible material, such as a conductive metal wire (e.g., refractory metal wire), patterned metal layer (e.g., molybdenum, tungsten, or other refractory metal layer), or other similar conductive structure. The heating elements 150 are connected to one or more conductive rods 155, which may extend along the length of the hollow shaft 114 of the pedestal 132. In some embodiments, the conductive rods 155 are positioned substantially parallel to the RF rod 122.

The conductive rods 155 couple the heating elements 150 to a heating power source 165, through one or more RF filters 160. The RF rod 122 and the conductive rods 155 are generally solid conductive elements (e.g., moderate diameter solid wire, non-stranded wire) that are formed from a conductive material, such as copper, nickel, gold, coated aluminum, a refractory metal. The RF filters 160 are generally either low-pass filters or band-stop filters that are configured to block RF energy from reaching the heating power source 165. In some embodiments, the heating power source 165 provides a non-RF, alternating current (AC) power to the heating elements 150. For example, the heating power source 165 may provide three-phase AC power at a frequency of approximately 60 Hertz.

In some embodiments, the RF filters 160 may be included in the heating assembly to provide a relatively greater impedance path to ground to minimize the amount of RF leakage to the heating elements 150. The RF filters 160 may be inserted in between heating elements 150 and the corresponding AC source(s) to attenuate RF energy and to suppress RF leakage current. In some configurations, the impedance of the RF electrode 112 to ground is substantially less than the impedance of the heating elements 150 to ground.

A system controller 134 controls the functions of the various components, such as the RF power sources 126 and 127, the drive system 105, the variable capacitors 128 and 139, and heating power source 165. The system controller 134 executes system control software stored in a memory 138. The system controller 134 comprises parts of or all of one or more integrated circuits (ICs) and/or other circuitry components. The system controller 134 may in some cases include a central processing unit (CPU) (not shown), memory (not shown), and support circuits (or I/O) (not shown). The CPU may be one of any form of computer processor that is used for controlling various system functions and support hardware and monitoring the processes being controlled by and within the chamber 100. The memory is coupled to the CPU, and may be one or more of a readily available memory, such as random access memory (RAM), read only memory (ROM), floppy disk, hard disk, or any other form of digital storage, local or remote. Software instructions (or computer instructions) and data may be coded and stored within the memory for instructing the CPU. The software instructions may include a program that determines which tasks are to be performed at any instant in time. The support circuits are also connected to the CPU for supporting the processor in a conventional manner. The support circuits may include cache, power supplies, clock circuits, timing circuits, input/output circuitry, subsystems, and the like.

In use, an RF path is established between the powered gas distribution manifold 118 and the RF electrode 112 via plasma. Further, by changing the capacitance of the variable capacitor 139, the impedance for the RF path through the RF electrode 112 changes, in turn, causing a change in the RF field coupled to the RF electrode 112 and a change in the RF return current through the RF electrode 112 and the RF rod 122. Therefore, the plasma in the process volume 106 may be modulated across the surface of the substrate 110 during plasma processing for improved processing uniformity.

Further, in some embodiments, an additional RF path is established between the powered gas distribution manifold 118 and the tuning ring 124. Additionally, by changing the capacitance of the variable capacitor 128, the impedance for the RF path through the tuning ring 124 changes, in turn, causing a change in the RF field coupled to the tuning ring 124. For example, a maximum current and corresponding minimum impedance of the tuning ring 124 can be achieved by varying the total capacitance of the variable capacitor 128. Therefore, the plasma in the process volume 106 may also be modulated across the surface of the substrate 110 using the additional RF path.

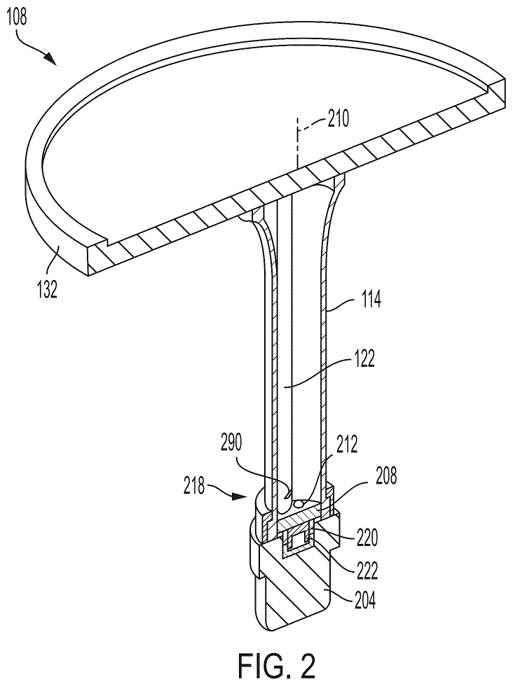

FIG. 2 depicts an isometric view of a substrate support 108 in accordance with at least some embodiments of the present disclosure. The RF rod 122 extends through the hollow shaft 114 of the substrate support 108 and is coupled to the pedestal 132 of the substrate support 108. In some embodiments, the RF rod 122 is disposed radially outward of a center 210 of the pedestal 132. In some embodiments, the RF rod 122 includes one or more slits 290 in the form of gaps to facilitate reducing stress on the RF rod 122 during thermal cycling. In some embodiments, the one or more slits 290 are disposed near a lower end of the RF rod 122. In some embodiments, a spacer plate 208 is disposed in the hollow shaft 114 to position the RF rod 122 therein. The spacer plate 208 may include one or more openings 212 to accommodate the RF rod 122 and the conductive rods 155 and maintain a spacing therebetween. In some embodiments, the spacer plate 208 is disposed in the hollow shaft 114 at a lower end 218 of the RF rod 122. The spacer plate 208 is generally made of an insulative material.

The hollow shaft 114 may be coupled to a lower block 204 made of a metal material, for example stainless steel. In some embodiments, a feedthrough 222 is disposed in the lower block 204 to provide an electrical feedthrough for the one or more conductive rods 155. In some embodiments, the feedthrough 222 is configured to facilitate a path to ground for the RF rod 122. In some embodiments, the lower end 218 of the RF rod 122 is coupled to a ceramic insulator 220 disposed in the lower block 204. The ceramic insulator 220 may separate the spacer plate 208 from the feedthrough 222 and the lower block 204 and be configured for higher temperature applications.

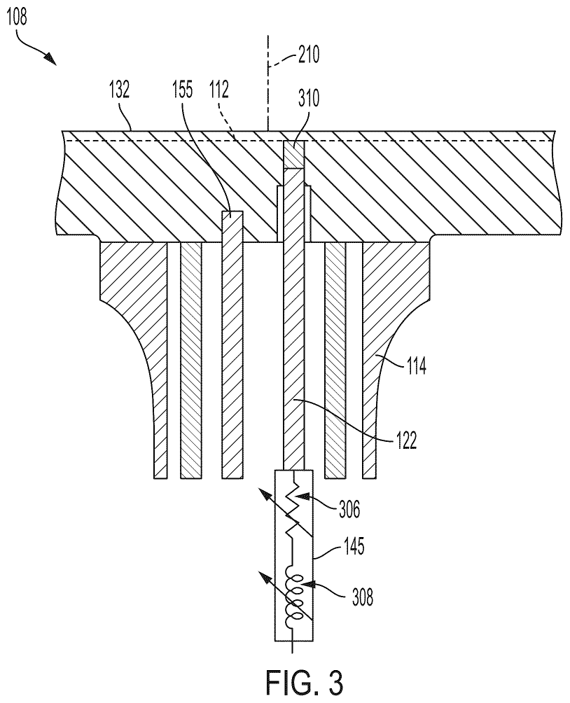

FIG. 3 depicts a schematic cross-sectional side view of a portion of a substrate support 108 in accordance with at least some embodiments of the present disclosure. The inventors have observed that an impedance of the substrate support 108 may be reduced by plating the RF rod 122 or brazing the RF rod 122 to the RF electrode 112. For example, the RF rod 122 may be plated with nickel, gold, or silver. In some embodiments, the plating has a thickness of about 30 to about 50 micrometers. In some embodiments, the RF rod 122 is brazed to the RF electrode 112 via a metal 310. In some embodiments, the metal 310 is made of copper, gold, silver, or nickel.

In some embodiments, the RF electrode 112 formed in the pedestal 132 is electrically coupled through RF rod 122 to an impedance adjustment device 145. In some embodiments, the impedance adjustment device 145 is disposed in the hollow shaft 114. In some embodiments, the impedance adjustment device 145 is at least partially disposed in the hollow shaft 114. In some embodiments, the impedance adjustment device 145 is disposed in the interior volume 103. In some embodiments, the impedance adjustment device 145 includes at least one of a variable inductor 308 or a variable resistor 306. The impedance adjustment device 145 may be configured to tune the substrate support 108 to a desired impedance value prior to installation in the chamber 100. The impedance adjustment device 145 generally does not adjust the impedance of the substrate support 108 during processing of the substrate 110. In other words, the impedance adjustment device 145 does not provide in-situ adjustment.

FIGS. 4A-5G depict various cross-sectional shapes of an RF rod 122 in accordance with at least some embodiments of the present disclosure. The inventors have observed that an impedance of the substrate support 108 may be reduced by increasing a cross-sectional area of the RF rod 122. In some embodiments, as depicted in FIG. 4A, the RF rod 122 has a circular cross-sectional shape. In some embodiments, the RF rod 122 has a non-circular cross-sectional shape. For example, FIG. 4B depicts the RF rod 122 having a star-like cross-sectional shape. FIG. 4C depicts the RF rod 122 having a triangular cross-section. FIG. 4D depicts the RF rod 122 having a square cross-sectional shape. In some embodiments, the RF rod 122 has a polygonal cross-sectional shape. For example, the RF rod 122 as shown in FIGS. 4C and 4D. In other examples, as depicted in FIG. 4E, the RF rod 122 may have a hexagonal cross-sectional shape, or as depicted in FIG. 4G, an octagonal cross-sectional shape. In some embodiments, as depicted in FIG. 4F, the RF rod 122 may have a square shape with indented features 420 at the 4 corners of the RF rod 122. In some embodiments, a diameter of the RF rod 122 is about 0.11 inches to about 0.14 inches. In some embodiments, the diameter of the RF rod 122 is about 0.12 to about 0.13 inches.

FIGS. 5A-5B depict various side profiles of an RF rod 122 in accordance with at least some embodiments of the present disclosure. The inventors have observed that an impedance of the substrate support 108 may be reduced by increasing a cross-sectional area of an upper portion of the RF rod 122 or reducing a length of the RF rod 122. In some embodiments, as depicted in FIG. 5A, the RF rod 122 includes an upper portion 510 and a lower portion 520. In some embodiments, a diameter 512 of the upper portion 510 is greater than a diameter of the lower portion 520. FIG. 5B depicts the RF rod 122 having a reduced length. In some embodiments, the length of the RF rod 122 may be about 7.5 to about 9 inches.

While the foregoing is directed to embodiments of the present disclosure, other and further embodiments of the disclosure may be devised without departing from the basic scope thereof.

1. A substrate support for a process chamber, comprising:
a pedestal having a support surface for supporting a substrate, one or more heating elements disposed therein, and an RF electrode disposed therein;
a hollow shaft coupled to a lower surface of the pedestal; and
an RF rod extending through the hollow shaft and coupled to the RF electrode, wherein the RF rod is plated with a material comprising gold or silver, and wherein the RF rod is coupled to an impedance adjustment device having at least one of a variable inductor or a variable resistor.

2. The substrate support of claim 1, wherein the impedance adjustment device is disposed radially inward of the hollow shaft.

3. The substrate support of claim 1, wherein the RF rod has a non-circular cross-sectional shape.

4. The substrate support of claim 3, wherein the RF rod has a polygonal cross-sectional shape.

5. The substrate support of claim 1, wherein the RF rod includes an upper portion and a lower portion, wherein a diameter of the upper portion is greater than a diameter of the lower portion.

6. The substrate support of claim 1, wherein the RF rod is brazed to the RF electrode with copper, gold, silver, or nickel.

7. The substrate support of claim 1, wherein the RF rod has a non-uniform diameter along a length of the RF rod.

8. The substrate support of claim 1, wherein a lower end of the RF rod is coupled to a ceramic insulator.

9. The substrate support of claim 1, wherein a diameter of the RF rod is about 0.11 inches to about 0.14 inches.

10. A substrate support for a process chamber, comprising:
a pedestal having one or more heating elements and an RF electrode disposed therein and a support surface for supporting a substrate;
a hollow shaft coupled to a lower surface of the pedestal; and
an RF rod extending through the hollow shaft and coupled to the RF electrode, wherein the RF rod comprises a first material plated with a second material different than the first material, and wherein the RF rod is coupled to an impedance adjustment device.

11. The substrate support of claim 10, wherein the impedance adjustment device includes at least one of a variable inductor or a variable resistor.

12. The substrate support of claim 10, wherein the impedance adjustment device is disposed in the hollow shaft.

13. The substrate support of claim 10, wherein at least one of:
the RF rod is brazed to the RF electrode with copper, gold, silver, or nickel, or
the second material comprises nickel, gold, or silver.

14. A process chamber, comprising:
a chamber body defining an interior volume therein;
a substrate support disposed in the interior volume and including a pedestal, having one or more heating elements and an RF electrode disposed therein and a support surface for supporting a substrate, and a hollow shaft coupled to a lower surface of the pedestal; and
an RF rod extending through the hollow shaft and coupled to the RF electrode, wherein the RF rod is plated with a material comprising gold or silver, and wherein the RF rod is coupled to an impedance adjustment device.

15. The process chamber of claim 14, wherein the impedance adjustment device has at least one of a variable inductor or a variable resistor.

16. The process chamber of claim 15, wherein the impedance adjustment device is disposed in the interior volume.

17. The process chamber of claim 14, wherein RF electrode comprises a mesh.

18. The process chamber of claim 14, further comprising a heating power source coupled to the one or more heating elements and one or more RF filters disposed between the heating power source and the one or more heating elements.

19. The process chamber of claim 14, further comprising a spacer plate disposed in the hollow shaft at a lower end of the RF rod.

20. The process chamber of claim 14, wherein the RF rod is disposed radially outward of a center of the pedestal.
